(19) United States
(12) Patent Application Publication
(10) Pub. No.: US 2026/0084128 A1
(43) Pub. Date: Mar. 26, 2026

(54) FLUID SUPPLY MECHANISM AND FLUID SUPPLY METHOD

(71) Applicant: HORIBA STEC, Co., Ltd., Kyoto-shi, Kyoto (JP)

(72) Inventors: Hidetaka YADA, Kyoto-shi (JP); Keisuke NISHIWAKI, Kyoto-shi (JP)

(21) Appl. No.: 19/111,005

(22) PCT Filed: Aug. 30, 2023
(86) PCT No.: PCT/JP2023/031488

§ 371 Date: Mar. 12, 2025

(30) Foreign Application Priority Data
Oct. 12, 2022 (JP) 2022-163948

(51) Int. Cl. B01J 4/00; C23C 16/455

(52) U.S. Cl. CPC B01J 4/008; C23C 16/45544

(57) ABSTRACT

A fluid supply mechanism 100 that repeats supply and stop of a fluid to a chamber CH, includes: a fluid supply path L1 communicating with the chamber CH; a tank T provided in the fluid supply path L1 and into which the fluid is introduced; and a downstream-side valve Vd provided at a downstream side of the tank T in the fluid supply path L1, in which an internal volume of the tank T changes due to deformation of the tank T.

### TECHNICAL FIELD

The present invention relates to a fluid supply mechanism and a fluid supply method.

### BACKGROUND ART

Conventionally, as one of film formation techniques in a semiconductor manufacturing process, there is a technique called an atomic layer deposition (ALD) method for supplying a material gas in a pulsed manner, and by using this technique, a thin film in an atomic unit can be formed on a substrate.

In this ALD method, a material gas is filled in a tank, and a secondary valve provided on a downstream side of the tank is opened and closed at a high speed to repeat supply and stop of the material gas.

In recent years, it has been required to supply a large flow rate of material gas in a pulsed manner due to, for example, an increase in a film formation area or the like. However, in the conventional configuration, the supply amount of the material gas depends on the Cv value of the secondary valve, and there is a limit to increase the flow rate.

Such a demand for increasing the flow rate of the material gas is common not only in the ALD method but also in a case where the material is continuously supplied to the chamber.

In order to solve such a problem, Patent Literature 1 discloses a configuration in which a piston is provided inside a tank, and after a material gas is introduced into the tank, the piston is moved to compress the material gas inside the tank, and a secondary valve is opened in this state to increase the flow rate of the material gas to be supplied.

However, with such a configuration using the piston, there is a concern that particles are generated inside the tank, and it is practically difficult to adopt the piston in a semiconductor manufacturing process.

### CITATION LIST

### Patent Literature

Patent Literature 1: JP 2010-84156 A

### SUMMARY OF INVENTION

### Technical Problem

Therefore, the present invention has been made to solve the above problems, and a main object thereof is to supply a large flow rate of fluid while suppressing generation of particles.

### Solution to Problem

A fluid supply mechanism according to the present invention is a fluid supply mechanism that repeats supply and stop of a fluid to a chamber, including: a fluid supply path communicating with the chamber; a tank provided in the fluid supply path and into which the fluid is introduced; and a downstream-side valve provided at a downstream side of the tank in the fluid supply path, in which an internal volume of the tank changes due to deformation of the tank.

According to the fluid supply mechanism configured as described above, the fluid is introduced into the tank in a state of having a large internal volume, and the tank is deformed from that state so that the internal volume of the tank becomes small. Therefore, a large flow rate of fluid can be supplied to the chamber, and since the tank itself is deformed, the generation of particles can also be suppressed.

A more specific embodiment includes an aspect in which the tank is deformed between a first form in which the internal volume is a first volume and a second form in which the internal volume is a second volume smaller than the first volume, the fluid is introduced into the tank in a state where the downstream-side valve is closed and the tank is in the first form, and the fluid is supplied from the tank to the chamber in a state where the downstream-side valve is opened and the tank is in the second form.

In the embodiment described above, there is a concern that the fluid in the tank flows backward to the upstream side when the tank is deformed from the first state to the second state.

Thus, it is preferable that the fluid supply mechanism further include an upstream-side valve provided at an upstream side of the tank in the fluid supply path, the fluid be introduced into the tank in the first form in a state where the upstream-side valve is opened, and the tank be deformed from the first form to the second form in a state where the upstream-side valve is closed.

With such a configuration, since the tank is deformed in a state where the upstream-side valve is closed, it is possible to prevent backflow of the fluid at the time of deformation.

It is preferable that deformation of the tank from one of the first form and the second form to another one and deformation from the other one to the one be repeated at a predetermined deformation timing, and opening and closing of the downstream-side valve be repeated at a predetermined opening and closing timing.

As described above, by controlling the deformation of the tank and the opening and closing of the downstream-side valve by time, the present invention can be applied without significantly changing the existing program.

It is preferable that the fluid supply mechanism include: a pressure sensor that detects a pressure in the tank; and a valve control unit that closes the upstream-side valve when a detection value of the pressure sensor reaches a threshold.

By closing the upstream-side valve at such a timing, the tank is then deformed from the first state to the second state, so that a standby state before the fluid is supplied to the chamber can be maintained in substantially the same state every time.

If the internal volume of the tank is known, the supply amount of the fluid can be obtained by monitoring the pressure of the tank.

Thus, it is preferable that the fluid supply mechanism include: a pressure sensor that detects a pressure of the tank; and a valve control unit that controls an opening degree of the downstream-side valve based on a detection value of the pressure sensor.

With such a configuration, the opening degree of the valve can be controlled based on the supply amount obtained from the detection value of the pressure sensor, and for example, the supply amount can be maintained constant or the supply amount can be gradually increased.

It is preferable that a plurality of the fluid supply paths be connected in parallel to each other, and the tank be provided in each of the plurality of fluid supply paths.

With such a configuration, for example, while the fluid is supplied from a certain tank to the chamber, the fluid is introduced into another tank, and thus after the supply from the former tank is finished, the fluid can be supplied from the latter tank to the chamber. Therefore, the supply and stop of the fluid to the chamber can be repeated at various timings.

It is difficult to quickly repeat the deformation of the tank if the time until the tank returns to the original shape after being deformed is long.

Thus, it is preferable that the fluid supply mechanism further include: a drive source that outputs a drive force for deforming the tank from the first state to the second state or from the second state to the first state; and a biasing member that applies a force to the tank in a direction opposite to the drive force to bias the tank from the second state to the first state or from the first state to the second state.

With such a configuration, after the tank is deformed by the drive force, the tank can be returned to the original shape by the biasing member, so that the deformation of the tank can be quickly repeated.

Another embodiment for quickly repeating the deformation of the tank includes an aspect in which the fluid supply mechanism further includes a drive source that outputs a drive force for deforming the tank from the first form to the second form and outputs a drive force for deforming the tank from the second form to the first form.

In addition, a fluid supply method according to the present invention is a fluid supply method using a fluid supply mechanism that repeats supply and stop of a fluid to a chamber, the fluid supply mechanism includes: a fluid supply path communicating with the chamber; a tank provided in the fluid supply path and into which the fluid is introduced; and a downstream-side valve provided at a downstream side of the tank in the fluid supply path, and the fluid supply method includes changing an internal volume of the tank by deforming the tank.

With such a fluid supply method, it is possible to exert the operation and effect similar to those of the fluid supply mechanism described above.

Furthermore, a fluid supply mechanism according to the present invention includes: a plurality of fluid supply paths communicating with the chamber and connected in parallel to each other; a tank provided in each of the plurality of fluid supply paths and into which the fluid is introduced; and a downstream-side valve provided at a downstream side of the tank in each of the plurality of fluid supply paths, in which an internal volume of the tank changes due to deformation of the tank.

According to the fluid supply mechanism configured as described above, not only in the configuration in which the supply and stop of the fluid to the chamber are repeated, but also in the configuration in which the fluid is continuously supplied to the chamber, it is possible to supply a large flow rate of fluid while suppressing generation of particles.

### Advantageous Effects of Invention

According to the present invention described above, it is possible to supply a large flow rate of fluid while suppressing generation of particles.

### BRIEF DESCRIPTION OF DRAWINGS

FIG. 1 is a schematic view illustrating a configuration of a fluid supply mechanism according to an embodiment of the present invention.

FIG. 2 is a diagram illustrating an on/off cycle of a downstream-side valve of the embodiment.

FIG. 3 is a schematic view illustrating a first form and a second form of a tank of the embodiment.

FIG. 4 is a schematic view illustrating a movable portion of the tank of the embodiment.

FIG. 5 is a schematic view illustrating a biasing member of the embodiment.

FIG. 6 is a functional block diagram illustrating functions of a control apparatus of the embodiment.

FIG. 7 is a schematic view illustrating an operation of the fluid supply mechanism of the embodiment.

FIG. 8 is a flowchart indicating an operation of the control apparatus of the embodiment.

FIG. 9 is a schematic view illustrating a configuration of a movable portion of another embodiment.

FIG. 10 is a schematic view illustrating a configuration of a fluid supply mechanism of another embodiment.

FIG. 11 is a schematic view illustrating a configuration of a fluid supply mechanism of another embodiment.

### DESCRIPTION OF EMBODIMENTS

Hereinafter, a fluid supply mechanism according to an embodiment of the present invention will be described with reference to the drawings.

### Apparatus Configuration

The fluid supply mechanism is used, for example, in an atomic layer deposition apparatus (hereinafter, also referred to as an ALD apparatus), and supplies a fluid to a chamber to be supplied in a pulsed (intermittent) manner. More specifically, the ALD apparatus is configured to repeat the supply of fluid to the chamber and the stoppage of the supply, and sequentially introduces at least two reactive precursor species into at least one substrate housed in the chamber.

Note that the fluid supplied to the chamber is, for example, a material gas obtained by vaporizing a liquid material. The material gas is a concept including a gas necessary for advancing a process in the chamber, such as a component gas for film formation and an etching gas. In addition, what is supplied to the chamber by the fluid supply mechanism may be various gases or liquids such as a liquid material itself, a material gas obtained by vaporizing the liquid material, and a mixed gas obtained by mixing the material gas and a carrier gas.

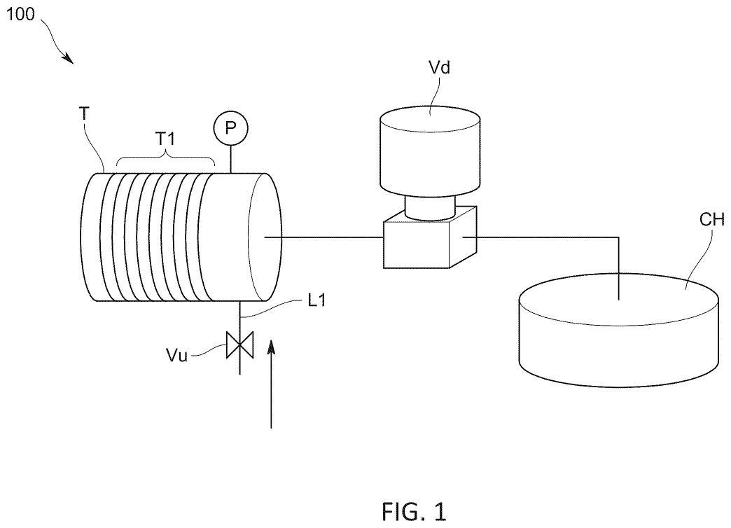

Specifically, as illustrated in FIG. 1, a fluid supply mechanism 100 includes at least a fluid supply path L1 communicating with a chamber CH, a tank T provided in the fluid supply path L1, and a downstream-side valve Vd provided at a downstream side of the tank T in the fluid supply path L1.

The fluid supply path L1 has an upstream-side end portion connected to a vaporizer (not illustrated) that vaporizes, for example, a liquid material, and a downstream-side end portion connected to the chamber CH. Note that the upstream-side end portion of the fluid supply path L1 is not necessarily connected to the vaporizer, and may be connected to various fluid sources. In addition, a mass flow controller (not illustrated) may be provided at an upstream side of the tank T in the fluid supply path L1.

The tank T functions as a reservoir into which a fluid is introduced and that stores the fluid, and has a known internal volume. The tank T of the present embodiment is provided with a pressure sensor P that detects the internal pressure. Since the tank T and its periphery are characterized, a detailed configuration will be described later.

The downstream-side valve Vd is provided between the tank T and the chamber CH, and is for supplying the fluid from the tank T to the chamber CH and stopping the supply of the fluid. That is, the fluid is supplied from the tank T to the chamber CH by opening the downstream-side valve Vd, and the supply of the fluid from the tank T to the chamber CH is stopped by closing the downstream-side valve Vd.

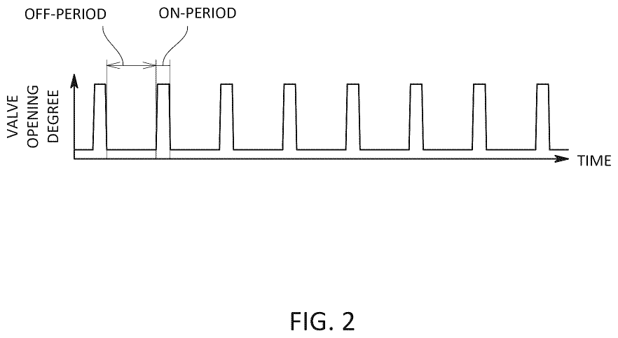

As illustrated in FIG. 2, the downstream-side valve Vd of the present embodiment is repeatedly opened or fully closed by pulse control in which the downstream-side valve Vd is repeatedly turned on and off at a predetermined cycle. The pulse width in the on-period is set to, for example, the order of 10 msec, and the entire cycle is set to, for example, the order of 100 msec. However, the pulse width is not limited thereto, and may be appropriately changed.

The downstream-side valve Vd only needs to be turned on and off at a high speed, and may be, for example, a pneumatic valve with improved responsiveness for the ALD process, a piezo valve using a piezo actuator, an electromagnetic valve, or various types of valves.

As illustrated in FIG. 1, the fluid supply mechanism 100 of the present embodiment further includes an upstream-side valve Vu provided at the upstream side of the tank T in the fluid supply path L1.

The upstream-side valve Vu is for introducing the fluid into the tank T and stopping the introduction of the fluid. That is, the fluid is introduced into the tank T by opening the upstream-side valve Vu, and the introduction of the fluid into the tank T is stopped by closing the upstream-side valve Vu.

Similarly to the downstream-side valve Vd, the upstream-side valve Vu of the present embodiment is repeatedly opened or fully closed by pulse control in which the upstream-side valve Vu is repeatedly turned on and off at a predetermined cycle. The pulse width in the on-period is set to, for example, the order of 10 msec, and the entire cycle is set to, for example, the order of 100 msec. However, the pulse width is not limited thereto, and may be appropriately changed.

The upstream-side valve Vu only needs to be turned on and off at a high speed, and may be, for example, a pneumatic valve with improved responsiveness for the ALD process, a piezo valve using a piezo actuator, an electromagnetic valve, or various types of valves.

The fluid supply mechanism 100 is characterized in that the internal volume of the tank T described above changes due to the deformation of the tank T.

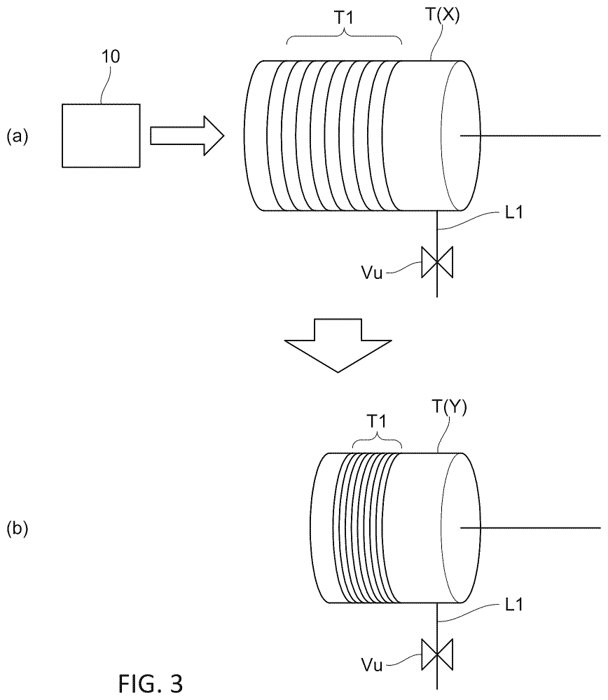

The internal volume of the tank T is variable due to its own deformation, and as illustrated in FIG. 3, the tank T is deformed between a first form X in which the internal volume is a first volume and a second form Y in which the internal volume is a second volume which is smaller than the first volume. Note that the first volume and the second volume are known.

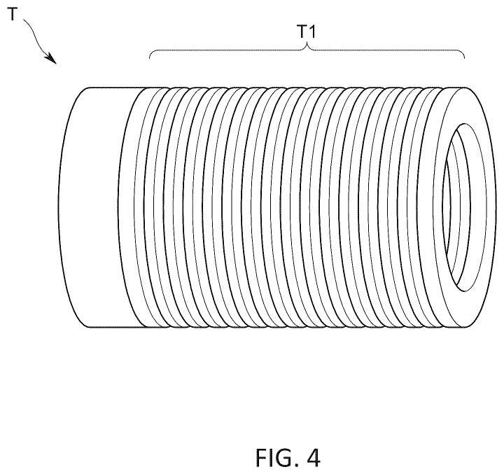

As illustrated in FIGS. 3 and 4, the tank T of the embodiment has, for example, a tubular shape that can expand and contract in the axial direction, and includes a movable portion T1 that partially or entirely expands and contracts in the axial direction. In the embodiment, the movable portion T1 is configured using, for example, a bellows. Note that, in FIG. 4, one opening of the tank T is opened for convenience of description, but this opening is closed during use.

As illustrated in FIG. 3, the fluid supply mechanism 100 of the present embodiment includes a drive source 10 that outputs a drive force for deforming the tank T from the first form X to the second form Y or from the second form Y to the first form X. Note that the power source of the embodiment is for transforming the tank T from the first form X to the second form Y.

The drive source 10 outputs, for example, a mechanical, electrical, or fluid drive force, and the drive force is applied to, for example, an end surface to which a pipe is not connected among end surfaces orthogonal to the axial direction of the tank T. Specifically, the drive source may be various sources configured using a motor, a pneumatic valve, a solenoid, a piezo element, or the like.

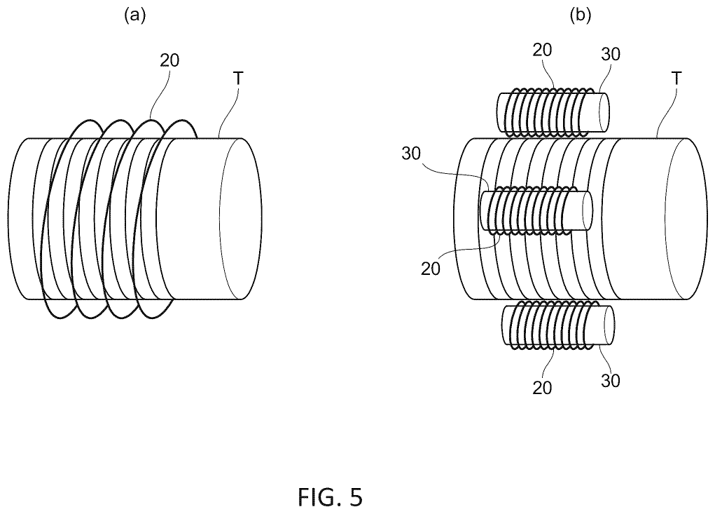

Furthermore, as illustrated in FIG. 5, the fluid supply mechanism 100 may include a biasing member 20 that applies a force to the tank T in a direction opposite to the above-described drive force to bias the tank T from the second form Y to the first form X or from the first form X to the second form Y. Note that the biasing member 20 of the embodiment biases the tank T from the second form Y to the first form X.

The biasing member 20 biases a restoring force of the tank T itself in which the tank T deformed from the first form X to the second form Y by the drive force described above tries to return from the second form Y to the first form X. Specifically, the biasing member 20 is one or a plurality of elastic bodies provided outside the tank T. The elastic body of the embodiment is provided so as to have, for example, a natural length in a state where the tank T is in the first form X and to contract from the natural length in a state where the tank T is in the second form Y. Note that the elastic body may be provided so as to have, for example, a natural length in a state where the tank T is in the second form Y, and to extend from the natural length in a state where the tank T is in the first form X. In this case, the elastic body biases the tank T from the first form X to the second form Y.

A specific aspect of the elastic body as the biasing member 20 includes a spring wound around an outer peripheral surface of the tank T as illustrated in FIG. 5 at (a), or a spring wound around a shaft member 30 attached to the tank T and expanding and contracting together with the tank T as illustrated in FIG. 5 at (b).

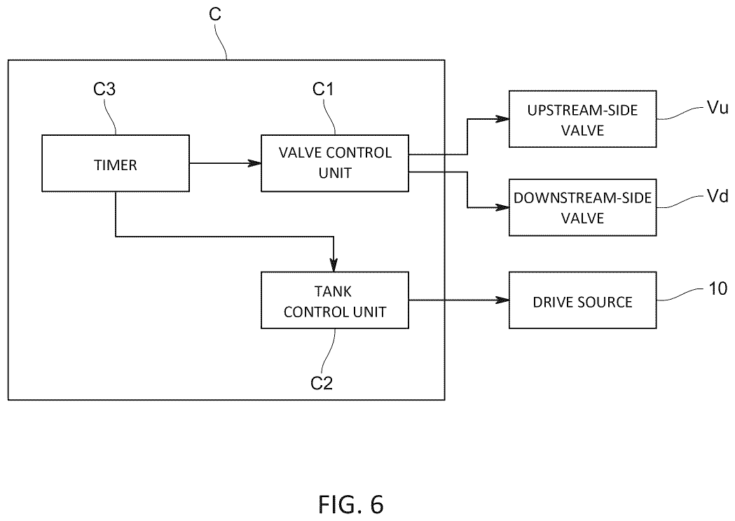

In such a configuration, as illustrated in FIG. 6, the fluid supply mechanism 100 includes a control apparatus C including a memory, a CPU, and the like, and the control apparatus C exerts functions as a valve control unit C1 and a tank control unit C2 by the CPU and peripheral equipment thereof cooperating with each other according to a program stored in the memory.

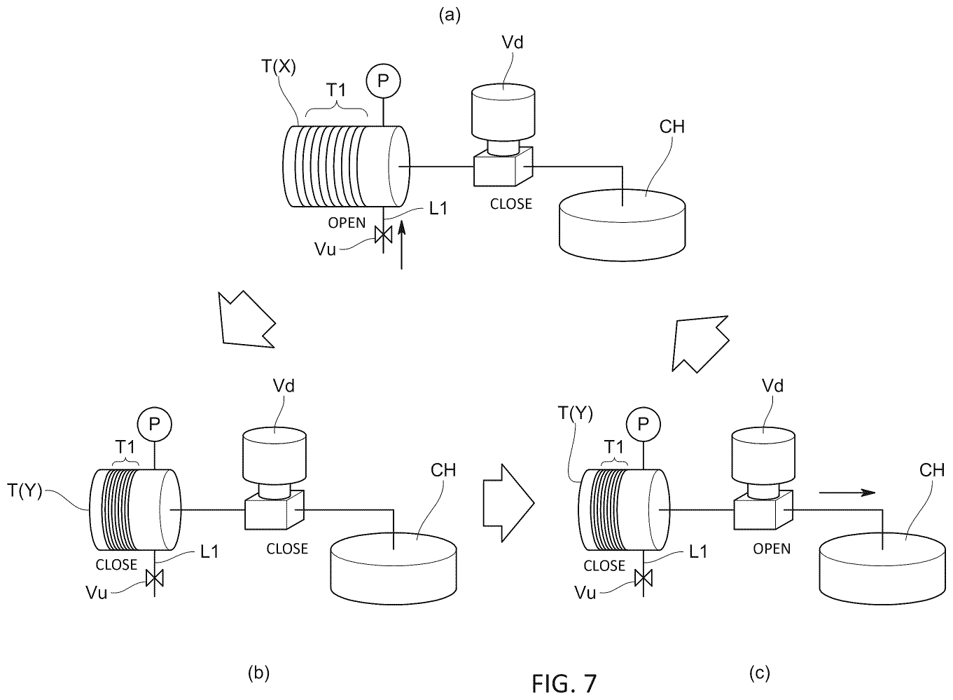

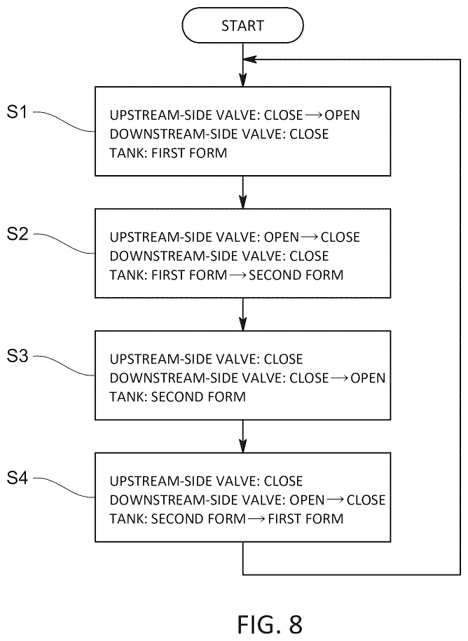

Hereinafter, the operation of the control apparatus C will be described with reference to the schematic view of FIG. 7 and the flowchart of FIG. 8 in order to also describe the function of each unit.

### Description of Operation

First, before the process is started, the upstream-side valve Vu and the downstream-side valve Vd are closed, and the tank T is in the first form X.

Then, when the process is started, the valve control unit C1 opens the upstream-side valve Vu (S1). At this time, the valve control unit C1 maintains the downstream-side valve Vd in a closed state, and the tank control unit C2 maintains the tank T in the first form X. As a result, as illustrated in FIG. 7 at (a), the fluid is introduced into the tank T in the first form X in a state where the upstream-side valve Vu is opened and the downstream-side valve Vd is closed.

Next, the valve control unit C1 closes the upstream-side valve Vu, and the tank control unit C2 controls the drive source 10 described above to deform the tank T from the first form X to the second form Y (S2). At this time, the valve control unit C1 maintains the downstream-side valve Vd in a closed state. As a result, as illustrated in FIG. 7 at (b), the fluid filled in the tank T is compressed.

Note that, in S2, the tank T is deformed from the first form X to the second form Y after the upstream-side valve Vu is closed in the present embodiment. In other words, in a state where the upstream-side valve Vu is closed, the tank T is deformed from the first form X to the second form Y. However, the upstream-side valve Vu may be closed while the tank T is being deformed from the first form X to the second form Y or furthermore, the upstream-side valve Vu may be closed promptly after the tank T is deformed from the first form X to the second form Y.

Subsequently, the valve control unit C1 opens the downstream-side valve Vd (S3). At this time, the valve control unit C1 maintains the upstream-side valve Vu in a closed state, and the tank control unit C2 maintains the tank T in the second form Y. As a result, as illustrated in FIG. 7 at (c), in a state where the downstream-side valve Vd is opened and the tank T is in the second form Y, the fluid is supplied from the tank T to the chamber CH.

Note that, in S2 and S3, the downstream-side valve Vd is opened after the tank T is deformed from the first form X to the second form Y in the present embodiment, but the downstream-side valve Vd may be opened while the tank T is being deformed from the first form X to the second form Y, or the tank T may be deformed from the first form X to the second form Y promptly after the downstream-side valve Vd is opened. An embodiment in which the downstream-side valve Vd is opened while the tank T is being deformed from the first form X to the second form Y includes an aspect in which the downstream-side valve Vd is opened when a detection value of a pressure sensor P provided in the tank T reaches a threshold.

Thereafter, the valve control unit C1 closes the downstream-side valve Vd, the tank control unit C2 turns off the drive force by the drive source 10 described above, and the tank T is deformed from the second form Y to the first form X by its own restoring force and/or the biasing force of the biasing member 20 (S4).

Note that, in S4, the tank T is deformed from the second form Y to the first form X after the downstream-side valve Vd is closed in the present embodiment. In other words, in a state where the downstream-side valve Vd is closed, the tank T is deformed from the second form Y to the first form X. However, the downstream-side valve Vd may be closed while the tank T is being deformed from the second form Y to the first form X or furthermore, the downstream-side valve Vd may be closed after the tank T is deformed from the second form Y to the first form X.

Then, the valve control unit C1 returns to the operation of S1, opens the upstream-side valve Vu, and returns to the state of FIG. 7 at (a).

By repeating the operations of S1 to S4 in this manner, the supply of the fluid to the chamber CH and the stop of the supply are alternately repeated.

As illustrated in FIG. 6, the control apparatus C of the present embodiment includes a timer C3, and the valve control unit C1 acquires a signal from the timer C3 and opens and closes the downstream-side valve Vd and the upstream-side valve Vu at each predetermined cycle. That is, the on-period in which the downstream-side valve Vd is opened and the off-period in which the downstream-side valve Vd is closed are repeated at a predetermined cycle, and the on-period in which the upstream-side valve Vu is opened and the off-period in which the upstream-side valve Vu is closed are repeated at a predetermined cycle. Note that the length of the on-period and the length of the off-period may be the same or different, or one or both may be variable. In addition, the cycle of opening and closing the upstream-side valve Vu and the cycle of opening and closing the downstream-side valve Vd may be the same or different.

As a result, the opening and closing of the downstream-side valve Vd are repeated at a predetermined first opening and closing timing, and the opening and closing of the upstream-side valve Vu are repeated at a predetermined second opening and closing timing.

In addition, the tank control unit C2 of the present embodiment acquires a signal from the timer C3 and turns on and off the drive source 10 at a predetermined cycle. That is, the on-period in which the drive force is output from the drive source 10 and the off-period in which the output is stopped are repeated at a predetermined cycle. Note that the length of the on-period and the length of the off-period may be the same or different, or one or both may be variable. The cycle of turning on and off the drive source 10 may be the same as or different from the cycle of turning on and off the downstream-side valve Vd or the cycle of turning on and off the upstream-side valve Vu described above.

As a result, the deformation of the tank T from one of the first form X and the second form Y to the other one and the deformation from the other one to the one are repeated at a predetermined deformation timing.

### Effects of the Present Embodiment

According to the fluid supply mechanism 100 configured as described above, the fluid is introduced into the tank T in the first form X having a large internal volume, the tank T is deformed from that state to the second form Y having a small internal volume, and then the fluid is supplied from the tank T to the chamber CH. Therefore, a large flow rate of fluid can be supplied to the chamber CH, and since the tank T itself is deformed, the generation of particles can also be suppressed.

In addition, since the tank T is deformed from the first form X to the second form Y in a state where the upstream-side valve Vu is closed, it is possible to prevent backflow of the fluid at the time of deformation.

Furthermore, since the opening and closing of the downstream-side valve Vd are repeated at a predetermined opening and closing timing, the present invention can be applied without significantly changing the existing program.

In addition, since the biasing member 20 biases the restoring force of the tank T itself, the deformation of the tank T can be quickly repeated after the tank T is deformed by the drive force.

### Other Embodiment Note that the present invention is not limited to the above embodiment.

For example, in the above embodiment, the upstream-side valve Vu is provided in the upstream of the tank T. However, when the influence of the backflow from a tank T is small, an upstream-side valve Vu does not need to be provided. In addition, the upstream-side valve Vu may be a check valve that prevents backflow from the tank T while enabling introduction of the fluid into the tank T.

Furthermore, in the above embodiment, the valve control unit C1 opens and closes the upstream-side valve Vu at a predetermined opening and closing timing. However, a valve control unit C1 may be configured to close an upstream-side valve Vu when a detection value of a pressure sensor P provided in a tank T reaches a threshold.

With such a configuration, by deforming the tank T from a first state to a second state after the upstream-side valve Vu is closed, a standby state before the fluid is supplied to a chamber CH can be maintained in substantially the same state every time.

Moreover, in the above embodiment, the valve control unit C1 opens and closes the downstream-side valve Vd at a predetermined opening and closing timing. However, the valve control unit C1 may be configured to close a downstream-side valve Vd when the detection value of the pressure sensor P described above decreases to a predetermined pressure value.

Note that, even when the downstream-side valve Vd is opened and closed based on the detection value of the pressure sensor P in this manner, by controlling the opening degree of the downstream-side valve Vd, the supply time (that is, the time during which the downstream-side valve Vd is opened) for supplying the fluid to the chamber CH can be adjusted to a desired time, and furthermore, the supply of the fluid to the chamber CH and the stop of the supply can be repeated at a desired cycle.

In addition, in the above embodiment, the tank control unit C2 repeats the deformation of the tank T at a predetermined deformation timing. However, in an operation of deforming a tank T to change the internal volume from a first volume to a second volume, when a detection value of a pressure sensor P reaches a threshold during the operation, it is considered that the tank T has reached the second volume, and a tank control unit C2 may be configured to maintain (adjust) the drive force applied from a drive source 10 to the tank T so as to maintain the pressure inside the tank T at that time.

By such control, it is possible to suppress variations in the pressure inside the tank T before the fluid is supplied to the chamber CH, and to suppress variations in the supply amount to the chamber CH.

Furthermore, the pressure sensor P may be used to confirm that the tank T has been deformed from a first form X to a second form Y. That is, when the detection value of the pressure sensor P reaches a target value, it is determined that the tank T is completely deformed into the second form Y, and the tank control unit C2 may be configured to maintain (adjust) the drive force applied from the drive source 10 to the tank T so as to maintain the tank T in the second form Y.

Note that, in a case where the drive source 10 deforms the tank T from the second form Y to the first form X, the pressure sensor P may be used to confirm that the tank T has been deformed from the second form Y to the first form X. That is, when the detection value of the pressure sensor P reaches the target value, it is determined that the tank T is completely deformed into the first form X, and the tank control unit C2 may be configured to maintain (adjust) the drive force applied from the drive source 10 to the tank T so as to maintain the tank T in the first form X.

If the internal volume of a tank T is known, the supply amount of the fluid can be obtained by monitoring the pressure of the tank T.

Therefore, a valve control unit C1 may control the opening degree of a downstream-side valve Vd based on a detection value of a pressure sensor P provided in the tank T.

A specific embodiment of the valve control unit C1 includes an aspect in which the actual supply amount supplied from the tank T to a chamber CH is calculated based on the internal volume of the tank T and the time change rate of the detection value of the pressure sensor P, and the opening degree of the downstream-side valve Vd is adjusted so that the actual supply amount approaches a preset target supply amount.

With such a configuration, since the opening degree of the valve is controlled based on the detection value of the pressure sensor P, for example, the supply amount can be maintained constant or gradually increased by setting the target flow rate to a constant flow rate or a gradually increasing flow rate.

Furthermore, by monitoring the pressure or concentration in the chamber CH, a valve control unit may be configured to control a downstream-side valve Vd based on the pressure or concentration, and a specific embodiment in this case includes an aspect in which the downstream-side valve Vd is opened when the pressure or concentration exceeds a predetermined threshold.

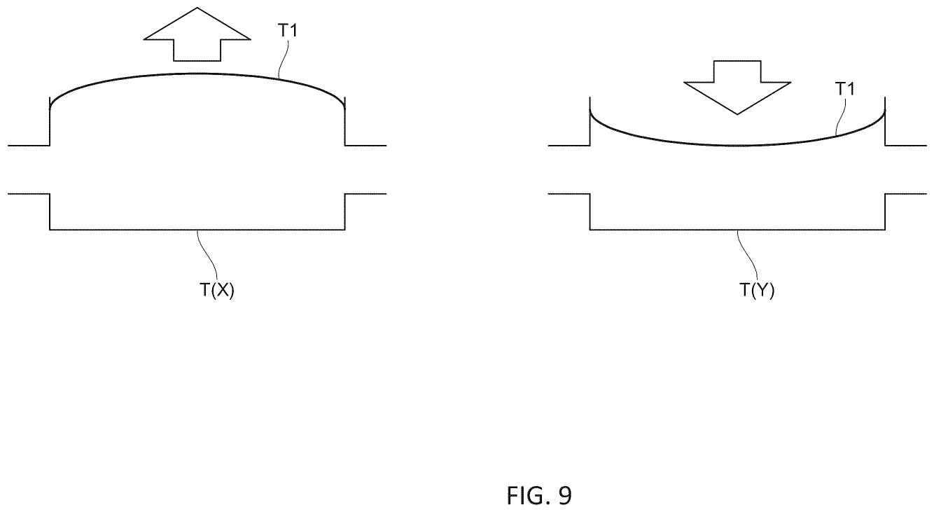

In the above embodiment, the bellows is used as the movable portion T1 of the tank T. However, as illustrated in FIG. 9, a movable portion T1 may have stretchability such as a diaphragm, and a specific embodiment in this case includes an aspect in which a part of a wall surface of a tank T is formed by the diaphragm.

In the above embodiment, the drive source 10 outputs the drive force for deforming the tank T from the first form X to the second form Y or from the second form Y to the first form X. However, a drive source 10 may output the drive force for deforming a tank T from a first form X to a second form Y and may output the drive force for deforming the tank T from the second form Y to the first form X. In this case, a biasing member 20 may bias the tank T from the first form X to the second form Y or from the second form Y to the first form X, or the biasing member 20 does not need to be provided.

In the above embodiment, one or a plurality of springs is described as the biasing member 20, but an elastic body such as a diaphragm or rubber may be used in addition to the springs.

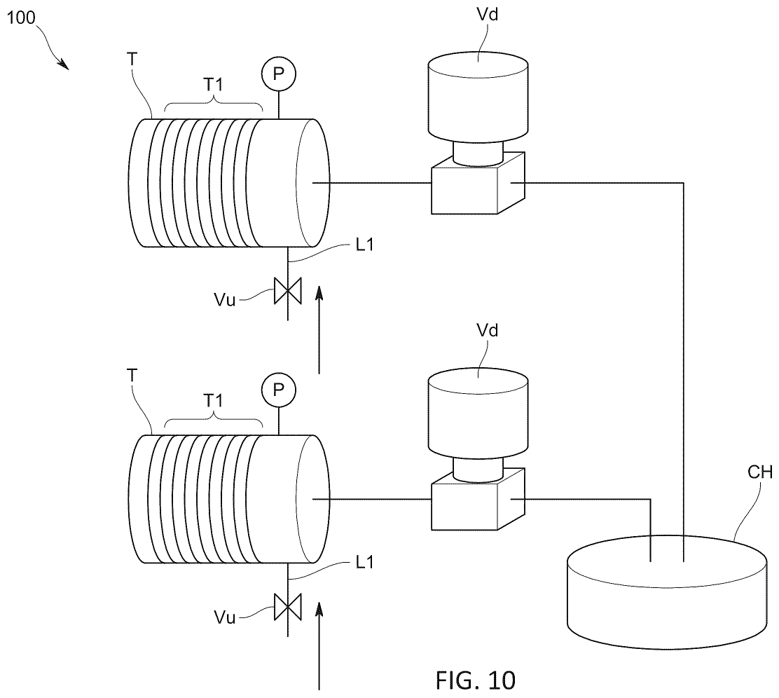

Furthermore, in the fluid supply mechanism 100 according to the present invention, as illustrated in FIG. 10, a plurality of fluid supply paths L1 may be connected in parallel to each other, and a tank T may be provided in each of the plurality of fluid supply paths L1.

With such a configuration, for example, while the fluid is supplied from a certain tank T to the chamber CH, the fluid is introduced into another tank T, and thus after the supply from the former tank T is finished, the fluid can be supplied from the latter tank T to the chamber CH. Therefore, the supply and stop of the fluid to the chamber CH can be repeated at various timings.

In addition, the fluid supply mechanism 100 according to the present invention is not limited to one that is used in an ALD apparatus and repeats supply and stop of fluid to the chamber CH.

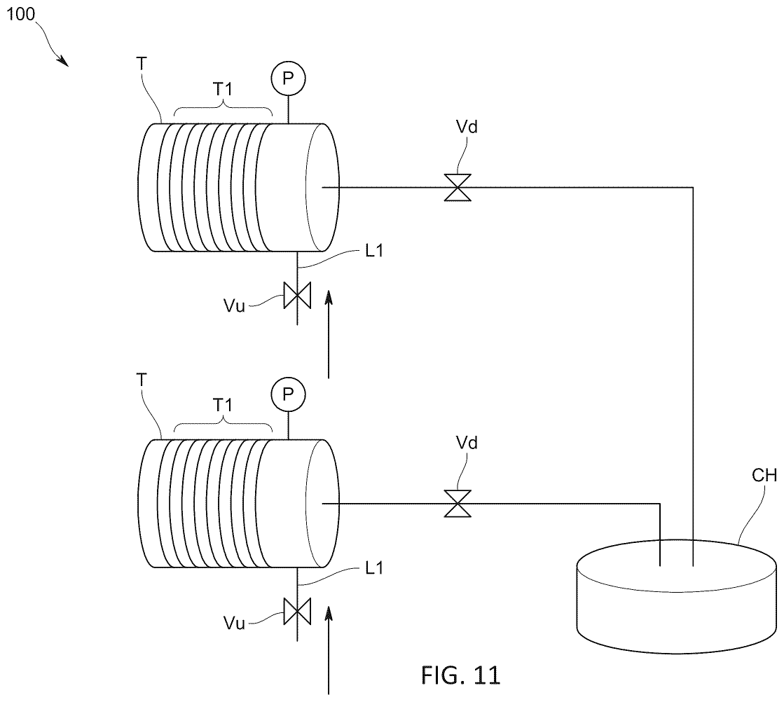

As illustrated in FIG. 11, an example of a fluid supply mechanism 100 includes: a plurality of fluid supply paths L1 communicating with a chamber CH and connected in parallel to each other; a tank T provided in each of the plurality of fluid supply paths L1 and into which a fluid is introduced; and a downstream-side valve Vd provided at a downstream side of the tank T in each of the plurality of fluid supply paths L1, in which an internal volume of the tank T changes due to deformation of the tank T.

In this configuration, the downstream-side valve Vd does not need to open and close at a high speed, and a cheaper on-off valve can be used.

According to the fluid supply mechanism 100 configured as described above, it is possible to supply a large flow rate of fluid while suppressing generation of particles even in a configuration in which the fluid is continuously supplied to the chamber CH.

In addition, various modifications and combinations of the embodiments may be made without departing from the gist of the present invention.

### INDUSTRIAL APPLICABILITY

According to the present invention, it is possible to supply a large flow rate of fluid while suppressing generation of particles.

### REFERENCE SIGNS LIST

100 fluid supply mechanism
CH chamber
L1 fluid supply path
T tank
Vd downstream-side valve
Vu upstream-side valve
P pressure sensor
X first form
Y second form
T1 movable portion
10 drive source
20 biasing member
30 shaft member
C control apparatus
C1 valve control unit
C2 tank control unit
C3 timer

1. A fluid supply mechanism that repeats supply and stop of a fluid to a chamber, the fluid supply mechanism comprising:
a fluid supply path communicating with the chamber;
a tank provided in the fluid supply path and into which the fluid is introduced; and
a downstream-side valve provided at a downstream side of the tank in the fluid supply path,
wherein an internal volume of the tank changes due to deformation of the tank.

2. The fluid supply mechanism according to claim 1, wherein
the tank is deformed between a first form in which the internal volume is a first volume and a second form in which the internal volume is a second volume smaller than the first volume,
the fluid is introduced into the tank in a state where the downstream-side valve is closed and the tank is in the first form, and
the fluid is supplied from the tank to the chamber in a state where the downstream-side valve is opened and the tank is in the second form.

3. The fluid supply mechanism according to claim 2, further comprising an upstream-side valve provided at an upstream side of the tank in the fluid supply path, wherein
the fluid is introduced into the tank in the first form in a state where the upstream-side valve is opened, and
the tank is deformed from the first form to the second form in a state where the upstream-side valve is closed.

4. The fluid supply mechanism according to claim 1, wherein
deformation of the tank from one of the first form and the second form to another one and deformation from the other one to the one are repeated at a predetermined deformation timing, and opening and closing of the downstream-side valve are repeated at a predetermined opening and closing timing.

5. The fluid supply mechanism according to claim 3, further comprising:
a pressure sensor that detects a pressure in the tank; and
a valve control unit that closes the upstream-side valve when a detection value of the pressure sensor reaches a threshold.

6. The fluid supply mechanism according to claim 1, further comprising:
a pressure sensor that detects a pressure of the tank; and
a valve control unit that controls an opening degree of the downstream-side valve based on a detection value of the pressure sensor.

7. The fluid supply mechanism according to claim 1, wherein
a plurality of the fluid supply paths is connected in parallel to each other, and
the tank is provided in each of the plurality of fluid supply paths.

8. The fluid supply mechanism according to claim 1, to further comprising:
a drive source that outputs a drive force for deforming the tank from the first form to the second form or from the second form to the first form; and
a biasing member that applies a force to the tank in a direction opposite to the drive force to bias the tank from the second form to the first form or from the first form to the second form.

9. The fluid supply mechanism according to claim 1, further comprising a drive source that outputs a drive force for deforming the tank from the first form to the second form and outputs a drive force for deforming the tank from the second form to the first form.

10. A fluid supply method using a fluid supply mechanism that repeats supply and stop of a fluid to a chamber, the fluid supply mechanism including:
a fluid supply path communicating with the chamber;
a tank provided in the fluid supply path and into which the fluid is introduced; and
a downstream-side valve provided at a downstream side of the tank in the fluid supply path, the fluid supply method comprising
changing an internal volume of the tank by deforming the tank.

11. A fluid supply mechanism comprising:
a plurality of fluid supply paths communicating with a chamber and connected in parallel to each other;
a tank provided in each of the plurality of fluid supply paths and into which a fluid is introduced; and
a downstream-side valve provided at a downstream side of the tank in each of the plurality of fluid supply paths,
wherein an internal volume of the tank changes due to deformation of the tank.
